(19) United States
(12) Patent Application Publication
(10) Pub. No.: US 2021/0021025 A1
(43) Pub. Date: Jan. 21, 2021

(54) ANTENNA PACKAGE AND IMAGE DISPLAY DEVICE INCLUDING THE SAME

(71) Applicant: DONGWOO FINE-CHEM CO., LTD., Jeollabuk-do (KR)

(72) Inventors: Byoung In KIM, Seoul (KR); Euk Kun YOON, Gyeonggi-do (KR); Byung Soo BANG, Gyeonggi-do (KR)

(21) Appl. No.: 16/930,414

(22) Filed: Jul. 16, 2020

(30) Foreign Application Priority Data
Jul. 17, 2019 (KR) 10-2019-0086468

(51) Int. Cl. H01Q 1/38; H01Q 1/40; H01Q 15/14; H01Q 1/22; H01Q 1/24

(52) U.S. Cl. CPC H01Q 1/38; H01Q 1/40; H01Q 1/243; H01Q 1/2266; H01Q 15/141

(57) ABSTRACT

An antenna package includes a base insulation layer, an antenna pattern being disposed on the base insulation layer and including a radiation pattern and a transmission line extending from the radiation pattern, a circuit protection layer formed on the base insulation layer to cover the transmission line and including a mounting hole through which an end portion of the transmission line is exposed, and an antenna driving integrated circuit chip inserted in the mounting hole to be electrically connected to the end portion of the transmission line. Signa reliability and spatial efficiency may be improve by an integration of the antenna pattern and the antenna driving integrated circuit chip.

### CROSS-REFERENCE TO RELATED APPLICATION AND CLAIM OF PRIORITY

This application claims priority to Korean Patent Applications No. 10-2019-0086468 filed on Jul. 17, 2019 in the Korean Intellectual Property Office (KIPO), the entire disclosure of which is incorporated by reference herein.

### BACKGROUND

### 1. Field

The present invention relates to an antenna package and an image display device including the same. More particularly, the present invention relates to an antenna package including an antenna pattern and a driving integrated circuit and an image display device including the same.

### 2. Description of the Related Art

As information technologies have been developed, a wireless communication technology such as Wi-Fi, Bluetooth, etc., is combined with a display device in, e.g., a smartphone form. In this case, an antenna may be combined with the display device to provide a communication function.

As mobile communication technologies have been rapidly developed, an antenna capable of operating a high-frequency or ultra-high frequency communication, e.g., 3G to 5G communication is needed in the display device.

However, as a driving frequency of the antenna is increased, a signal loss may be easily caused. Further, as a length of a signaling path is increased, the signal loss may become greater.

Additionally, when an intermediate circuit structure such as a flexible printed circuit board (FPCB) is used to electrically connect a driving integrated circuit chip for controlling an antenna radiation/feeding and the antenna with each other, an additional signal loss may be caused.

Further, as a thin-layered display device having a large display area is developed, a local space for accommodating the antenna may be decreased.

### SUMMARY

According to an aspect of the present invention, there is provided an antenna package having improved operational reliability and structural efficiency.

According to an aspect of the present invention, there is provided an image display device including an antenna package with improved operational reliability and structural efficiency.

The above aspects of the present invention will be achieved by one or more of the following features or constructions:

(1) An antenna package, including: a base insulation layer; an antenna pattern disposed on the base insulation layer, the antenna pattern including a radiation pattern and a transmission line extending from the radiation pattern; a circuit protection layer formed on the base insulation layer to cover the transmission line, the circuit protection layer including a mounting hole through which an end portion of the transmission line is exposed; and an antenna driving integrated circuit chip inserted in the mounting hole to be electrically connected to the end portion of the transmission line.

(2) The antenna package according to the above (1), wherein the circuit protection layer includes a liquid crystal polymer.

(3) The antenna package according to the above (1), wherein a glass transition temperature of the circuit protection layer is 300° C. or more.

(4) The antenna package according to the above (1), wherein the base insulation layer includes a display area and a non-display area, and the radiation pattern is disposed on the display area, and the transmission line is electrically connected to the antenna driving integrated circuit chip on the non-display area.

(5) The antenna package according to the above (4), further comprising a transparent protective layer formed on a portion of the base insulation layer of the display area to cover the radiation pattern.

(6) The antenna package according to the above (5), wherein the transparent protective layer includes cyclo olefin polymer (COP).

(7) The antenna package according to the above (4), further comprising a supporting plate disposed on a bottom surface of the base insulation layer in the non-display area to face the antenna driving integrated circuit chip in a thickness direction.

(8) The antenna package according to the above (4), further comprising a transparent protective layer disposed on a bottom surface of the base insulation layer in the display area, wherein the transparent protective layer includes cyclo olefin polymer (COP).

(9) The antenna package according to the above (1), further comprising a plating layer formed on the transmission line.

(10) The antenna package according to the above (9), wherein the antenna driving integrated circuit chip is directly connected to the transmission line via the plating layer.

(11) The antenna package according to the above (1), further comprising a mounting pad integrally formed with the end portion of the transmission line to connect the transmission line and the antenna driving integrated circuit chip with each other.

(12) The antenna package according to the above (1), further comprising a ground pattern disposed on a top surface of the circuit protection layer.

(13) The antenna package according to the above (1), wherein the radiation pattern includes a mesh structure.

(14) An image display device comprising the antenna package according to exemplary embodiments as described above.

In an antenna package according to exemplary embodiments of the present invention, a transmission line of an antenna pattern may be directly connected to an antenna driving integrated circuit (IC) chip through, e.g., a plating layer. Accordingly, for example, a conductive intermediate structure such as a flexible printed circuit board (FPCB) or an anisotropic conductive film (ACF) may be omitted, and the transmission line of the antenna pattern may be directly connected to a mounting pad of the driving IC chip so that a length of a feeding path may become shorter.

Thus, a signal loss from a radiation pattern of the antenna pattern may be suppressed, and impedance mismatching due to an insertion of the conductive intermediate structure may be prevented.

For example, the antenna driving IC chip may be inserted into a mounting hole included in a high heat-resistance liquid crystal polymer layer formed on a base insulation layer. Thus, in a surface mounting process such as, a soldering process, thermal damages to the package may be prevented.

### BRIEF DESCRIPTION OF THE DRAWINGS

FIGS. 1 and 2 are schematic top planar and cross-sectional views, respectively, illustrating an antenna package in accordance with exemplary embodiments.

FIGS. 3 to 5 are schematic cross-sectional views illustrating an antenna package in accordance with some exemplary embodiments.

FIG. 6 is a schematic top planar view illustrating a display device in accordance with exemplary embodiments.

### DETAILED DESCRIPTION OF THE EMBODIMENTS

According to exemplary embodiments of the present invention, there is provided an antenna package including an antenna pattern and an antenna driving integrated circuit chip which may be directly and electrically connected to each other in a package, and having improved signaling efficiency and reliability. Further, an image display device including the antenna package is also provided.

Hereinafter, the present invention will be described in detail with reference to the accompanying drawings. However, those skilled in the art will appreciate that such embodiments described with reference to the accompanying drawings are provided to further understand the spirit of the present invention and do not limit subject matters to be protected as disclosed in the detailed description and appended claims.

The terms “upper”, “lower”, etc., is used to indicate relative locations between different elements and is not intended to designate an absolute position.

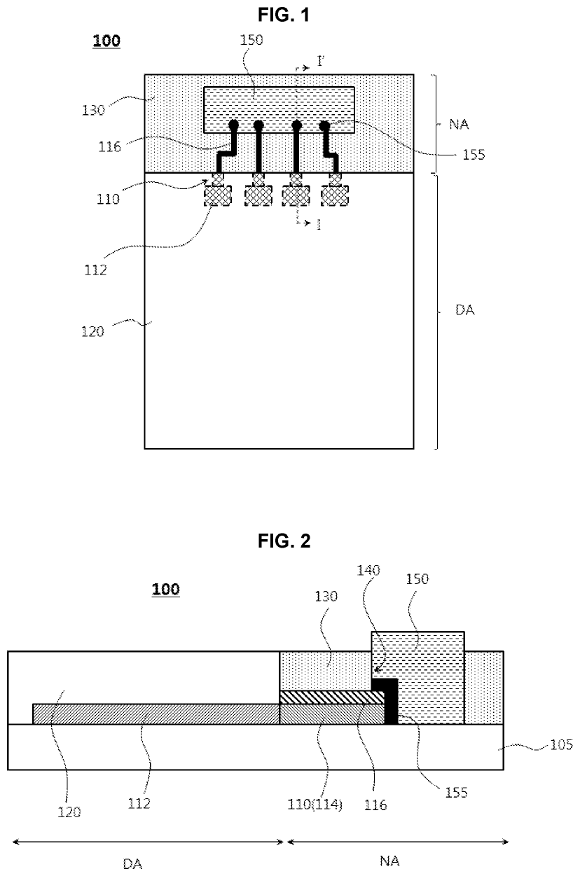

FIGS. 1 and 2 are schematic top planar and cross-sectional views, respectively, illustrating an antenna package in accordance with exemplary embodiments. For example, FIG. 2 is a cross-sectional view cut along a line I-I′ of FIG. 1.

Referring to FIGS. 1 and 2, an antenna package 100 may include an antenna pattern 110 and an antenna driving integrated circuit chip 150 (hereinafter, abbreviated as a driving IC chip) disposed on a base insulation layer 105.

For example, the base insulation layer 105 may serve as a supporting layer on which the antenna pattern 110 may be formed. In some embodiments, the base insulation layer 105 may serve as an intermediate layer or a detachment layer for separating the antenna package 100 from a carrier substrate (not illustrated) after forming the antenna package 100 on the carrier substrate.

In this case, the base insulation layer 105 may include an organic polymer. Non-limiting examples of the organic polymer may include a polyimide-based polymer, a polyvinyl alcohol-based polymer, a polyamic acid-based polymer, a polyamide-based polymer, a polyethylene-based polymer, a polystyrene-based polymer, a polynorbornene polymer, a phenylmaleimide copolymer, a polyazobenzene-based polymer, a polyphenylenephthalamide-based polymer, a polyester-based polymer, a polymethyl methacrylate-based polymer, a polyarylate-based polymer, a cinnamate-based polymer, a coumarin-based polymers, a phthalimidine-based polymer, a chalcone-based polymers, an aromatic acetylene-based polymer, etc. These may be used alone or in a combination thereof.

In some embodiments, the base insulation layer 105 may include a glass or transparent resin film. The transparent resin film may include, e.g., cyclic olefin polymer (COP), polyethylene terephthalate (PET), polyacrylate (PAR), polyetherimide (PEI), polyethylene naphthalate (PEN), polyphenylene sulfide (PPS), polyallylate, polyimide (PI), cellulose acetate propionate (CAP), polyethersulfone (PES), cellulose triacetate (TAC), polycarbonate (PC), cyclic olefin copolymer (COC), polymethyl methacrylate (PMMA), etc.

The base insulation layer 105 may be divided into a display area DA and a non-display area NA. Accordingly, the antenna package 100 may also be divided into the display area DA and the non-display area NA.

The display area DA may be, for example, an area from which an image is implemented in an image display device. In some embodiments, when the antenna package 100 is combined with the image display device, the display area DA may be an area in which sensing electrodes of a touch sensor, an optical film such as a polarizing plate, etc., may be disposed.

The non-display area NA may correspond to, e.g., a light blocking area or a bezel area of an image display device.

The antenna pattern 110 may include a radiation pattern 112 and a transmission line 114. As illustrated in FIG. 1, the radiation pattern 112 may be located at least partially on the display area DA. The transmission line 114 may be branched from the radiation pattern 112 and may extend onto the non-display area NA.

The transmission line 114 may serve as, e.g., a feeding line or a signal line of the antenna pattern 110. The transmission line 114 and the radiation pattern 112 may be formed as a substantially integral single member.

The radiation pattern 112 and/or the transmission line 114 may be formed of silver (Ag), gold (Au), copper (Cu), aluminum (Al), platinum (Pt), palladium (Pd), chromium (Cr), titanium (Ti), tungsten (W), niobium (Nb), tantalum (Ta), vanadium (V), iron (Fe), manganese (Mn), cobalt (Co), nickel (Ni), tin (Sn), zinc (Zn), molybdenum (Mo), calcium (Ca), or an alloy thereof. These may be used alone or in a combination thereof. For example, the radiation pattern 112 may be formed of silver (Ag) or a silver alloy (e.g., a silver-palladium-copper (APC) alloy), or copper or a copper alloy (e.g., a copper-calcium (CuCa) alloy) for implementing a low resistance and a fine line width.

The radiation pattern 112 and/or the transmission line 114 may include a transparent conductive oxide such as indium tin oxide (ITO), indium zinc oxide (IZO), zinc oxide (ZnO), indium zinc tin oxide (IZTO), cadmium tin oxide (CTO), etc.

In some embodiments, the radiation pattern 112 and/or the transmission line 114 may have a multi-layered structure such as a triple-layered structure of a transparent conductive oxide layer-metal layer-transparent conductive oxide layer. In this case, flexible properties may be improved and resistance may be reduced by the metal layer while corrosion resistance and transparency may be enhanced by the transparent conductive oxide layer.

In an embodiment, the radiation pattern 112 and/or the transmission line 114 may be formed of a mesh structure including the above-described conductive material to improve transparency or transmittance. In an embodiment, the radiation pattern 112 and/or the transmission line 114 may be formed of a solid thin film structure including the conductive material as described above for reducing signal loss and resistance.

A plating layer 116 may be formed on the transmission line 114. The plating layer 116 may be formed by, e.g. a metal plating. In some embodiments, the plating layer 116 may be selectively formed only on a portion of the transmission line 114 in the non-display area NA. Accordingly, a reduction of transparency in the display area DA by the plating layer 116 may be prevented.

The plating layer 116 may be provided as a substantially integral member with the transmission line 114 to serve as an integral feeding line or signal line.

As described above, the transmission line 114 may extend onto the non-display area NA, and an end portion of the transmission line 114 may be electrically connected to the driving IC chip 150.

In exemplary embodiments, the driving IC chip 150 may be substantially directly connected to the transmission line 114. For example, a direct connection between the antenna pattern 110 and the driving IC chip 150 by a surface mounting technology (SMT) via a mounting pad 155 may be implemented without an intermediate conductive connecting member such as an anisotropic conductive film (ACF).

Thus, signal loss, resistance increase, antenna impedance mismatching, etc., caused by the intermediate conductive connecting member may be suppressed or reduced.

The mounting pad 155 may have, e.g.me, a ball grid array (BGA) shape for performing the SMT process. The mounting pad 155 may be substantially integrated with the plating layer 116 to be provided as a substantially single member.

In exemplary embodiments, a circuit protection layer 130 covering the transmission line 114 may be formed on a portion of the base insulation layer 105 on the non-display area NA. A mounting hole 140 exposing an end portion of the transmission line 114 and the plating layer 116 may be formed in the circuit protection layer 130, and a driving IC chip 150 may be inserted into the mounting hole 140. Subsequently, the SMT process such as a soldering process may be performed to provide the substantially direct connection between the transmission line 114 and the driving IC chip 150.

In some embodiments, the circuit protection layer 130 may include a liquid crystal polymer (LCP) having a high heat resistance. For example, the circuit protection layer 130 may include the LCP having a glass transition temperature (Tg) of 300° C. or higher.

The circuit protection layer 130 may be formed of the LCP having the high heat resistance capable of sufficiently enduring the SMT process on the non-display area NA. Thus, the direct connection between the transmission line 114 of the antenna pattern 110 and the driving IC chip 150 may be easily achieved as described above.

In some embodiments, a transparent protective layer 120 may be formed on a portion of the base insulation layer 105 of the display area DA. The transparent protective layer 120 may cover the radiation pattern 112 of the antenna pattern 110 and may protect the antenna pattern 110 during the SMT process as described above.

The transparent protective layer 120 may include a transparent resin material having high transparency and high heat resistance. Preferably, for example, the transparent protective layer 120 may include a cyclic olefin polymer (COP) having a glass transition temperature (Tg) of 200° C. or higher, preferably 300° C. or higher.

As illustrated in FIG. 1, a plurality of the antenna patterns 110 may be arranged in an array shape to be electrically connected to the driving IC chip 150. For example, a plurality of the antenna patterns 110 may be individually or commonly fed and controlled through one driving IC chip 150.

In some embodiments, a ground line (not illustrated) may be disposed between the transmission lines 114 of the neighboring antenna patterns 110. Signal interference and noise between the neighboring antenna patterns 110 may be shielded or absorbed by the ground line.

According to exemplary embodiments as described above, the direct connection of the driving IC chip 150 and the transmission line 114 may be implemented using the high heat-resistant circuit protection layer 130 and the mounting hole 140 on the non-display area NA. Thus, a signal length may be decreased, and a total area or volume of the non-display area NA may be also decreased.

Further, the radiation pattern 112 may be positioned on the display area DA, and the area of the non-display area NA may be further reduced while suppressing the signal loss.

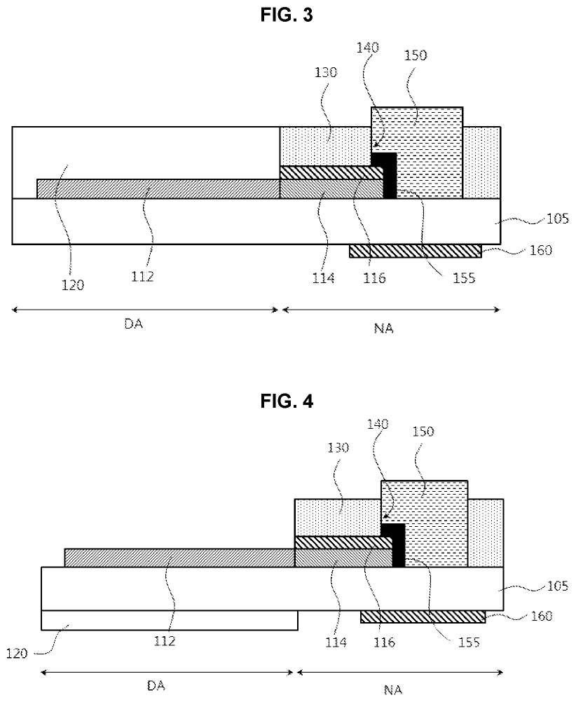

FIGS. 3 to 5 are schematic cross-sectional views illustrating an antenna package in accordance with some exemplary embodiments. Detailed descriptions on elements and structures substantially the same as or similar to those described with reference to FIGS. 1 and 2 are omitted herein.

Referring to FIG. 3, a supporting plate 160 may be disposed on a bottom surface of a portion of the base insulation layer 105 in the non-display area NA. The supporting plate 160 may include a metallic material such as Stainless Use Steel (SUS).

The supporting plate 160 may face or overlap the driving IC chip 150 in a thickness direction with the base insulation layer 105 interposed therebetween. For example, the supporting plate 160 may be formed to entirely cover the mounting hole 140 when projected in a planar view. Accordingly, the antenna package 100 or the base insulation layer 105 may be prevented from being deformed or damaged when mounting the driving IC chip 150 in the mounting hole 140 by the SMT process.

Referring to FIG. 4, the transparent protective layer 120 may be formed on a bottom surface of a portion of the base insulation layer 105 in the display area DA. As described above, the transparent protective layer 120 may include the high heat-resistant COP.

In this case, the transparent protective layer 120 and the supporting plate 160 may be disposed on the bottom surface of the base insulation layer 105 in the display area DA and the non-display area NA, respectively, so that reliability during the SMT process may be enhanced.

In an embodiment, the transparent protective layer 120 may be entirely formed on the bottom surface of the base insulating layer 105 throughout the display area DA and the non-display area NA. In this case, the supporting plate 160 may be omitted.

Referring to FIG. 5, a ground pattern 170 may be disposed on a top surface of the circuit protection layer 130. Noises between the neighboring transmission lines 114 or from the driving IC chip 150 may be shielded or absorbed by the ground pattern 170.

In an embodiment, the ground pattern 170 may be electrically connected to the above-mentioned ground line (not illustrated) between the transmission lines 114 in the circuit protection layer 130.

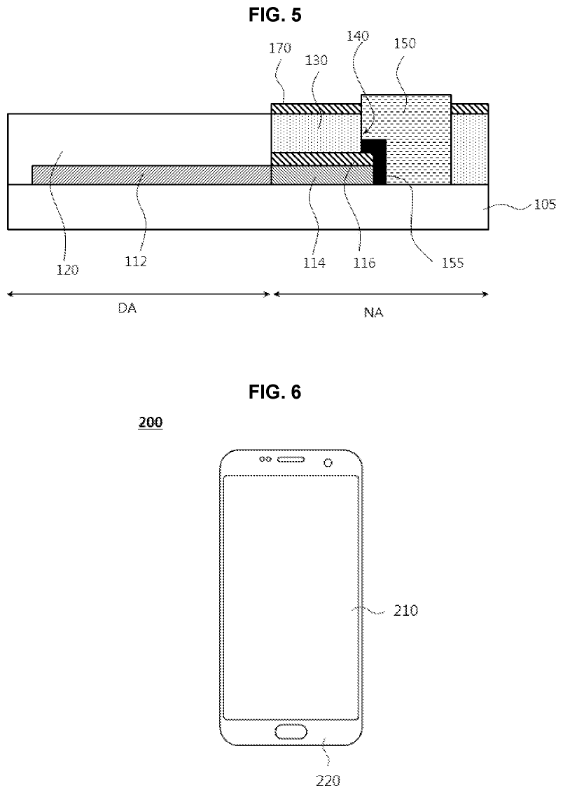

FIG. 6 is a schematic top planar view illustrating a display device in accordance with exemplary embodiments.

Referring to FIG. 6, an image display device 200 may be fabricated as a smart phone shape, and FIG. 6 illustrates a front face or a window face of the image display device 200. The front face of the image display device may include a display area 210 and a peripheral area 220. The display area 210 may substantially correspond to the display area DA of the antenna package 100 as described above. The peripheral area 220 may substantially correspond to the non-display area NA of the antenna package 100 as described above.

The antenna package 100 may be disposed under the front face of the image display device 200, for example, may be disposed on the display panel. In this case, at least a portion of the transmission line 114 included in the antenna package 100 and the driving IC chip 150 may be disposed in the peripheral area 220 to prevent image quality degradation in the display area 210.

The radiation pattern 112 of the antenna pattern 110 may be at least partially superimposed over the display area 210. In this case, the radiation pattern 112 may include a mesh structure, and a reduction of transmittance due to the radiation pattern 112 may be prevented.

As described above, an intermediate structure such as FPCB and ACF may be omitted, and the driving IC chip 150 and the antenna pattern 110 may be packaged in a single film structure. Accordingly, the image display device provided with a thin-layered and highly reliable communication structure may be achieved by utilizing the antenna package.

What is claimed is:

1. An antenna package, comprising:
a base insulation layer;
an antenna pattern disposed on the base insulation layer, the antenna pattern comprising a radiation pattern and a transmission line extending from the radiation pattern;
a circuit protection layer formed on the base insulation layer to cover the transmission line, the circuit protection layer including a mounting hole through which an end portion of the transmission line is exposed; and
an antenna driving integrated circuit chip inserted in the mounting hole to be electrically connected to the end portion of the transmission line.

2. The antenna package according to claim 1, wherein the circuit protection layer comprises a liquid crystal polymer.

3. The antenna package according to claim 1, wherein a glass transition temperature of the circuit protection layer is 300° C. or more.

4. The antenna package according to claim 1, wherein the base insulation layer includes a display area and a non-display area; and
the radiation pattern is disposed on the display area, and the transmission line is electrically connected to the antenna driving integrated circuit chip on the non-display area.

5. The antenna package according to claim 4, further comprising a transparent protective layer formed on a portion of the base insulation layer of the display area to cover the radiation pattern.

6. The antenna package according to claim 5, wherein the transparent protective layer comprises cyclo olefin polymer (COP).

7. The antenna package according to claim 4, further comprising a supporting plate disposed on a bottom surface of the base insulation layer in the non-display area to face the antenna driving integrated circuit chip in a thickness direction.

8. The antenna package according to claim 4, further comprising a transparent protective layer disposed on a bottom surface of the base insulation layer in the display area, wherein the transparent protective layer comprises cyclo olefin polymer (COP).

9. The antenna package according to claim 1, further comprising a plating layer formed on the transmission line.

10. The antenna package according to claim 9, wherein the antenna driving integrated circuit chip is directly connected to the transmission line via the plating layer.

11. The antenna package according to claim 1, further comprising a mounting pad integrally formed with the end portion of the transmission line to connect the transmission line and the antenna driving integrated circuit chip with each other.

12. The antenna package according to claim 1, further comprising a ground pattern disposed on a top surface of the circuit protection layer.

13. The antenna package according to claim 1, wherein the radiation pattern includes a mesh structure.

14. An image display device comprising the antenna package according to claim 1.
